(19) United States
(12) Patent Application Publication
(10) Pub. No.: US 2025/0267784 A1
(43) Pub. Date: Aug. 21, 2025

(54) HYBRID CONDUCTOR-VAPOR CHAMBER HEAT SINK FOR HIGH POWER THIN ENVELOPE APPLICATIONS

(71) Applicant: Ciena Corporation, Hanover, MD (US)

(72) Inventors: Peter Ajersch, Ottawa (CA); Trevor Meunier, Kemptville (CA)

(21) Appl. No.: 18/582,737

(22) Filed: Feb. 21, 2024

(51) Int. Cl. H05K 1/02; H05K 7/20

(52) U.S. Cl. CPC H05K 1/021; H05K 7/20309; H05K 7/20318; H05K 7/20336; H05K 7/20409; H05K 7/20509; H05K 2201/066

(57) ABSTRACT

A hybrid conductor-vapor chamber heat sink including: an inner planar member disposed adjacent to, in part, a printed circuit board and, in part, a device disposed on the printed circuit board; an outer planar member coupled to the inner planar member to form a sealed vapor chamber cavity adapted to contain a fluid; and a solid high thermal conductivity structure disposed between the inner planar member and the outer planar member within the vapor chamber cavity, where a center section of the solid high thermal conductivity structure is located coincident with a middle portion of the device and one or more perimeter sections of the solid high thermal conductivity structure are located coincident with one or more areas outside a perimeter of the device on the printed circuit board. The solid high thermal conductivity structure provides a thermal conduction path and the vapor chamber provides a thermal mass transfer path.

### TECHNICAL FIELD

The present disclosure relates generally to the telecommunications and optical networking fields. More particularly, the present disclosure relates to a hybrid conductor-vapor chamber heat sink for high power thin envelope applications.

### BACKGROUND

In the telecommunications and optical networking fields, it is often necessary to mount a heat sink on or adjacent to a device, such as a central processing unit (CPU), a complementary metal oxide semiconductor (CMOS) device, an application specific integrated circuit (ASIC), a field programmable gate array (FPGA), etc., disposed on a printed circuit board (PCB) to transfer heat away from the device with minimal thermal resistance. Conventional heat sinks include solid copper heat sinks and vapor chamber (VC) heat sinks.

A solid copper heat sink is limited in its cooling effectiveness by the conductivity of the heat sink (typically 385 W/mK), the geometry of the heat sink, and remote factors (such as air speed, etc.). In some applications, the envelope for the heat sink is thin (e.g., <1 mm), in which case the heat sink is primarily a base with no fins. In such a case, there is significant thermal resistance between the copper over the center of the device and the copper adjacent to the device (typically on the order of 10-20 degrees C. when used for a 50 W device). This leads to limited cooling effectiveness and potentially compromises device operation.

A VC heat sink constrained to a similar envelope (e.g., <1 mm) also has limited cooling effectiveness. If the total heat load into the VC heat sink is sufficiently low, then the VC heat sink will work better than the solid copper heat sink. However, for heat loads on the order of 50 W, a conventional VC heat sink will go into a “dry out” failure mode in which the liquid phase partially or fully evaporates before it is fully wicked back to the intended evaporator region of the heat sink, which would generally lie over the heat source being cooled, at which point the cooling effectiveness of the VC heat sink will be inferior to that of the solid copper heat sink. Such envelope constraints and heat loads are relatively common in high power telecommunications and optical networking applications.

The present background is provided as illustrative environmental context only and should not be construed to be limiting in any manner. It will be readily apparent to those of ordinary skill in the art that the principles and concepts of the present disclosure may be implemented in other environmental contexts equally, without limitation.

### SUMMARY

The present disclosure provides a hybrid conductor-VC heat sink for high power thin envelope applications that creates two parallel heat load paths over/adjacent to a device: (1) a solid high thermal conductivity material path and (2) a vapor transport path. This arrangement of solid high thermal conductivity material and vapor transport sections in a thin envelope (e.g., <1 mm) over/adjacent to the device ensures that the vapor section carries an amount of heat less than the total device power due to the presence of the solid thermal conductivity material section, and less than the peak heat flux (Qmax) rating of the vapor section, such that the vapor section does not go into dry out. Thin envelope applications are common in, but are not limited to, situations in which high power devices are disposed on the secondary side of a PCB. It should be noted that the condensation section(s) of the hybrid conductor-VC heat sink may be disposed adjacent to the device, where envelope constraints may be less without the presence of the device in these areas.

In one embodiment, the present disclosure provides a hybrid conductor-vapor chamber heat sink including: an inner planar member adapted to be disposed adjacent to, in part, a printed circuit board and, in part, a device disposed on the printed circuit board; an outer planar member coupled to the inner planar member to form a sealed vapor chamber cavity adapted to contain a fluid; and a solid high thermal conductivity structure disposed between the inner planar member and the outer planar member within the vapor chamber cavity, where a center section of the solid high thermal conductivity structure is located coincident with a middle portion of the device and one or more perimeter sections of the solid high thermal conductivity structure are located coincident with one or more areas outside a perimeter of the device on the printed circuit board. The solid high thermal conductivity structure provides a thermal conduction path to transfer heat from the center section of the solid high thermal conductivity structure to the one or more perimeter sections of the solid high thermal conductivity structure and correspondingly from the middle portion of the device to the one or more areas outside the perimeter of the device within the vapor chamber cavity. The vapor chamber cavity provides a thermal mass transfer path to transfer heat from an evaporation portion of the vapor chamber cavity, where the fluid undergoes phase change from liquid to vapor, to a condensation portion of the vapor chamber cavity, where the fluid undergoes phase change from vapor to liquid, and correspondingly from the middle portion of the device to the one or more areas outside the perimeter of the device within the vapor chamber cavity. The thermal conduction path takes a portion of a heat load of the device and the thermal mass transfer path takes another portion of the heat load of the device, such that the vapor chamber cavity does not enter a dry out mode. The hybrid conductor-vapor chamber heat sink further includes one or more of an inner wick layer and an outer wick layer disposed within the vapor chamber cavity between the inner planar member and the outer planar member. Optionally, the inner planar member defines a conformal recess in which the device is disposed, where the vapor chamber cavity is relatively thinner in an area of the conformal recess and relatively thicker around the conformal recess, and where the solid high thermal conductivity structure is located, at least in part, coincident with the conformal recess within the vapor chamber cavity. The hybrid conductor-vapor chamber heat sink further includes a plurality of pillar structures disposed between the inner planar member and the outer planar member and adapted to maintain the integrity of the vapor chamber cavity. A thermal interface material may be disposed between the inner planar member and a surface of the device. Optionally, the solid high thermal conductivity structure divides the vapor chamber cavity into a plurality of separate vapor chamber cavities. Optionally, the inner planar member, the outer planar member, and the solid high thermal conductivity structure are each manufactured from a material such as a metallic material (e.g., copper), graphite, or the like that very effectively and efficiently conducts heat.

In another embodiment, the present disclosure provides a network element including: a printed circuit board; a device disposed on the printed circuit board; and a hybrid conductor-vapor chamber heat sink. The hybrid conductor-vapor chamber heat sink includes: an inner planar member adapted to be disposed adjacent to, in part, the printed circuit board and, in part, the device; an outer planar member coupled to the inner planar member to form a sealed vapor chamber cavity adapted to contain a fluid; and a solid high thermal conductivity structure disposed between the inner planar member and the outer planar member within the vapor chamber cavity, where a center section of the solid high thermal conductivity structure is located coincident with a middle portion of the device and one or more perimeter sections of the solid high thermal conductivity structure are located coincident with one or more areas outside a perimeter of the device on the printed circuit board. The solid high thermal conductivity structure provides a thermal conduction path to transfer heat from the center section of the solid high thermal conductivity structure to the one or more perimeter sections of the solid high thermal conductivity structure and correspondingly from the middle portion of the device to the one or more areas outside the perimeter of the device within the vapor chamber cavity. The vapor chamber cavity provides a thermal mass transfer path to transfer heat from an evaporation portion of the vapor chamber cavity, where the undergoes phase change from liquid to vapor, to a condensation portion of the vapor chamber cavity, where the fluid undergoes phase change from vapor to liquid, and correspondingly from the middle portion of the device to the one or more areas outside the perimeter of the device within the vapor chamber cavity. The thermal conduction path takes a portion of a heat load of the device and the thermal mass transfer path takes another portion of the heat load of the device, such that the vapor chamber cavity does not enter a dry out mode. The hybrid conductor-vapor chamber heat sink further includes one or more of an inner wick layer and an outer wick layer disposed within the vapor chamber cavity between the inner planar member and the outer planar member. Optionally, the inner planar member defines a conformal recess in which the device is disposed, where the vapor chamber cavity is relatively thinner in an area of the conformal recess and relatively thicker around the conformal recess, and where the solid high thermal conductivity structure is located, at least in part, coincident with the conformal recess within the vapor chamber cavity. The hybrid conductor-vapor chamber heat sink further includes a plurality of pillar structures disposed between the inner planar member and the outer planar member and adapted to maintain the integrity of the vapor chamber cavity. A thermal interface material may be disposed between the inner planar member and a surface of the device. Optionally, the solid high thermal conductivity structure divides the vapor chamber cavity into a plurality of separate vapor chamber cavities. Optionally, the inner planar member, the outer planar member, and the solid high thermal conductivity structure are each manufactured from a material such as a metallic material (e.g., copper), graphite, or the like that very effectively and efficiently conducts heat.

In a further embodiment, the present disclosure provides a method for cooling a device disposed on a printed circuit board including: providing a thermal conduction path to transfer heat from a middle portion of the device to the one or more areas outside the perimeter of the device within a vapor chamber cavity; and providing a thermal mass transfer path to transfer heat from the middle portion of the device to the one or more areas outside the perimeter of the device within the vapor chamber cavity; where the thermal conduction path takes a portion of a heat load of the device and the thermal mass transfer path takes another portion of the heat load of the device, such that the vapor chamber cavity does not enter a dry out mode. The thermal mass transfer path includes the vapor chamber cavity containing a fluid provided between an inner planar member and an outer planar member of a hybrid conductor-vapor chamber heat sink, the vapor chamber cavity transferring heat from the evaporation portion of the vapor chamber cavity, where the fluid undergoes phase change from liquid to vapor, to a condensation portion of the vapor chamber cavity, where the fluid undergoes phase change from vapor to liquid. The thermal conduction path includes a solid high thermal conductivity structure disposed between the inner planar member and the outer planar member within the vapor chamber cavity, where a center section of the solid high thermal conductivity structure is located coincident with a middle portion of the device and one or more perimeter sections of the solid high thermal conductivity structure are located coincident with one or more areas outside the perimeter of the device, the solid high thermal conductivity structure transferring heat from the center section of the solid high thermal conductivity structure to the one or more perimeter sections of the solid high thermal conductivity structure.

It will be readily apparent to those of ordinary skill in the art that aspects and features of each of the described embodiments may be incorporated, omitted, and/or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 illustrates the hybrid conductor-VC heat sink of the present disclosure coupled to a PCB;

FIG. 2 further illustrates the hybrid conductor-VC heat sink coupled to the PCB;

FIG. 3 illustrates the hybrid conductor-VC heat sink coupled to the PCB over/adjacent to a device;

FIG. 4 further illustrates the hybrid conductor-VC heat sink coupled to the PCB over/adjacent to the device;

FIG. 5 further illustrates the hybrid conductor-VC heat sink coupled to the PCB, highlighting various cross-section views;

FIG. 6 further illustrates the hybrid conductor-VC heat sink coupled to the PCB over/adjacent to the device in one of the cross-section views;

FIG. 7 further illustrates the hybrid conductor-VC heat sink coupled to the PCB over/adjacent to the device in another of the cross-section views, highlighting a detailed view;

FIG. 8 further illustrates the hybrid conductor-VC heat sink coupled to the PCB over/adjacent to the device in the detailed view;

FIG. 9 illustrates one example embodiment of the hybrid conductor-VC heat sink;

FIG. 10 illustrates another example embodiment of the hybrid conductor-VC heat sink;

FIG. 11 illustrates a further example embodiment of the hybrid conductor-VC heat sink; and

FIG. 12 illustrates the hybrid conductor-VC heat sink of FIG. 10 in an exploded view.

It will be readily apparent to those of ordinary skill in the art that aspects and features of each of the illustrated embodiments may be incorporated, omitted, and/or combined as desired in a given application, without limitation.

### DETAILED DESCRIPTION

Again, the present disclosure provides a hybrid conductor-VC heat sink for high power thin envelope applications that creates two parallel heat load paths over/adjacent to a device: (1) a solid high thermal conductivity material path and (2) a vapor transport path. This arrangement of solid high thermal conductivity material and vapor transport sections in a thin envelope (e.g., <1 mm) over/adjacent to the device ensures that the vapor section carries an amount of heat less than the total device power due to the presence of the solid high thermal conductivity material section, and less than the Qmax rating of the vapor section, such that the vapor section does not go into dry out. Thin envelope applications are common in, but are not limited to, situations in which high power devices are disposed on the secondary side of a PCB. It should be noted that the condensation section(s) of the hybrid conductor-VC heat sink may be disposed adjacent to the device, where envelope constraints may be less without the presence of the device in these areas.

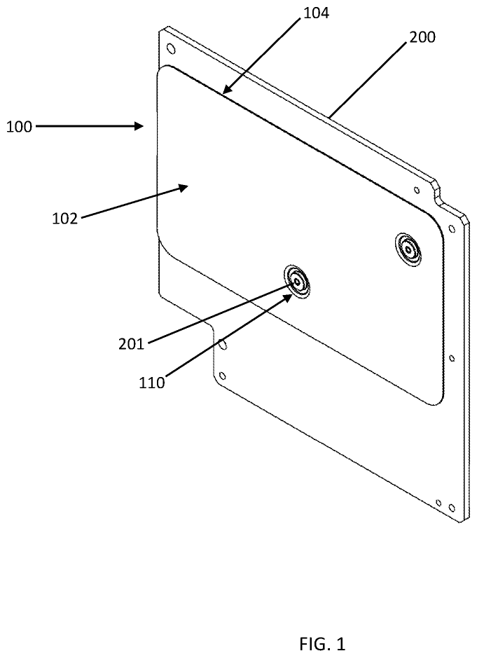

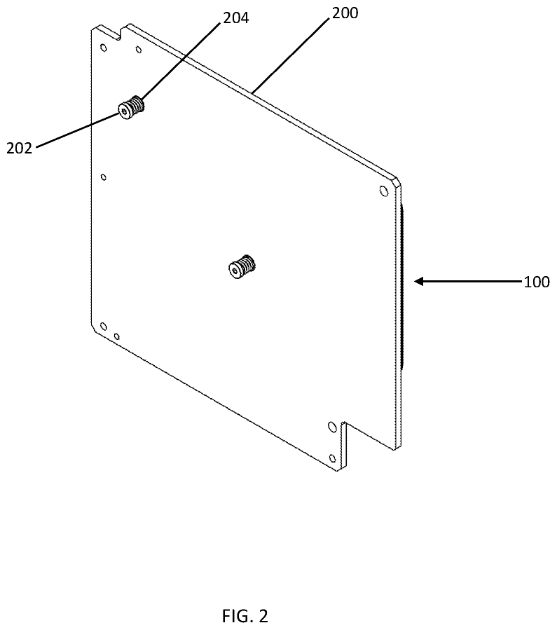

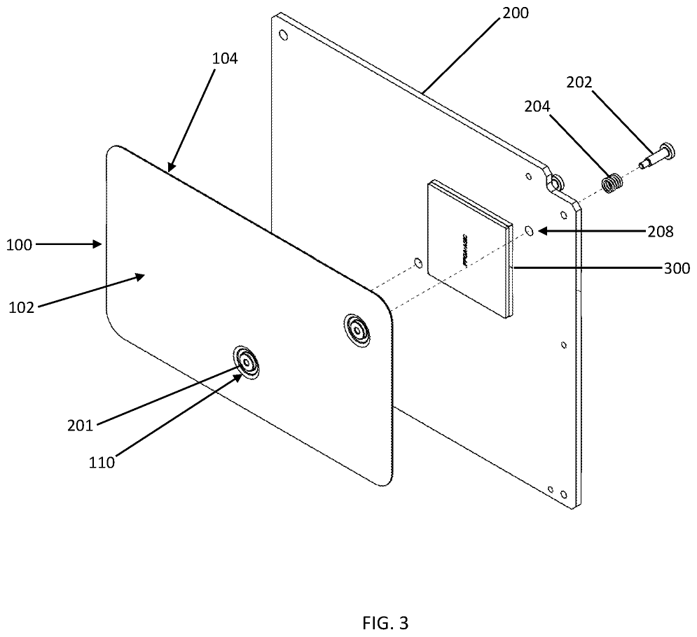

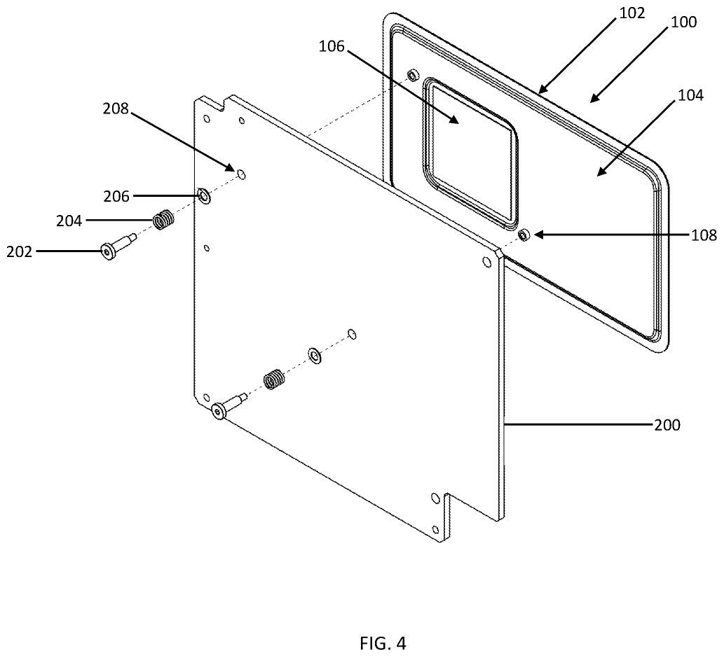

Referring to FIGS. 1-4, the VC heat sink 100 is attached to the first side of the PCB 200 using a plurality of nuts 201, shoulder screws 202, and/or other fasteners disposed through/around the VC heat sink 100 and the PCB 200, with the device 300 disposed between a portion of the VC heat sink 100 and a portion of the PCB 200. In this configuration, the VC heat sink 100 may be disposed over/adjacent to the device 300 or may act as a “lid” for the device 300. It should be noted that the first side of the PCB 200 is denoted as “first” only to distinguish it from the opposed second side of the PCB 200. The first side of the PCB 200 could be a top side, a bottom side, a left side, a right side, a primary side, a secondary side, etc. The plurality of nuts 201, shoulder screws 202, and/or other fasteners incorporate a plurality of springs 204 and washers 206 disposed on the second side of the PCB 200 that serve to bias the VC heat sink 100 towards the PCB 200 and against the intervening device 300, thereby promoting thermal contact between the VC heat sink 100 and the device 300. It will be readily apparent to those of ordinary skill in the art that other suitable mechanisms to couple the VC heat sink 100 to the PCB 200 and bias the VC heat sink 100 towards the device 300 may be used equally, without limitation. This aspect is not a focus of the present disclosure.

The VC heat sink 100 includes an outer planar member 102 (more indirectly adjacent to the device 300 and the PCB 200) and an inner planar member 104 (more directly adjacent to the device 300 and the PCB 200), both manufactured from a high thermal conductivity material, such as a metallic material (e.g., copper), graphite, or the like that effectively and efficiently conducts heat-which is what is meant by “high thermal conductivity” as used, excluding no materials that fulfill this function. The outer planar member 102 and the inner planar member 104 may be manufactured from the same or different materials and are joined together to form a sealed internal planar cavity in which a fluid (liquid and vapor) and other components can be contained to perform heat transfer functions. The outer planar member 102 and the inner planar member 104 have length and width dimensions greater than those of the device 300, such that the VC heat sink 100 covers more surface area of the PCB 200 than the device 300. The sealed internal planar cavity has a thickness that may vary from between <1 mm to several mms, depending on the available envelope adjacent to the PCB 200 and the desired heat transfer characteristics. As illustrated, the inner planar member 104 may define a conformal recess 106 in which the device 300 is received, such that the device 300 is partially encompassed within the inner planar member 104 when the VC heat sink 100 is coupled to the PCB 200 over/adjacent to the device 300. Further, the outer planar member 102, the inner planar member 104, and the PCB 200 may define a plurality of holes and/or standoffs 108, 208 for orienting and separating the VC heat sink 100 on and with respect to the PCB 200 and/or the device 300. Generally, the inner planar member 104 makes thermal contact with the surface of the device 300, either directly or through a thermal interface material, such as in the region of the conformal recess 106. The outer planar member 102 may include conformal recesses 110 for accommodating heads of the Nuts 201, such that the nuts 201, shoulder screws 202, and/or other fasteners do not effectively expand the height of the VC heat sink 100 within the envelope.

Thus, the VC heat sink 100 is thermally coupled to the surface of the device 300 (CPU, CMOS, ASIC, FPGA, etc.) on the PCB 200 and is used to spread heat from the device 300 to regions away from the device 300 with low thermal resistance. The heat is ultimately liberated into the air flow of the associated system via natural or forced convection, or into a cold plate thermally coupled to the VC heat sink 100 (the cold plate is not a focus of the present disclosure). Due to system constraints, the VC heat sink 100 may be limited to a small thickness, for example <1 mm when used as a heat spreader on a height restricted PCB secondary side device 300. Using standard VC technology and fabrication techniques, such a thickness constraint limits the maximum cooling effectiveness of a VC. If such a thin VC with standard construction is used to cool a 50 W device, for example, the VC will go into a dry out failure mode, in which evaporation is compromised, and will effectively be worse at cooling the device than a solid copper construction.

As described, the VC heat sink 100 is mounted to the device 300 with an applied pressure achieved, for example, through a combination of the nuts 201, shoulder screws 202, springs 204, and washers 206, while other mechanisms may alternatively be utilized. The thermal interface material reduces the thermal resistance of the contact between the inner planar member 104 and the surface of the device 300.

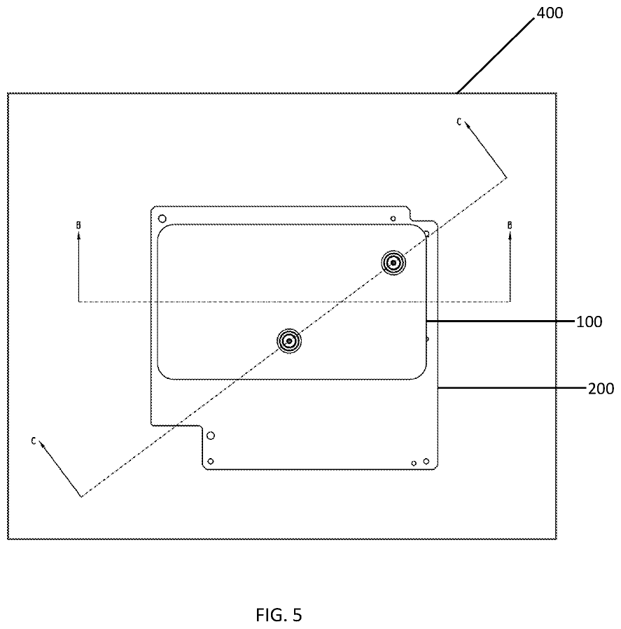

FIG. 5 illustrates the VC heat sink 100 coupled to the PCB within the broader context of a network element 400, highlighting various cross-section views.

The primary focus of the present disclosure is on the internal construction of the VC heat sink 100 itself, which uses a combination of solid high thermal conductivity material construction and VC construction in such a manner that heat from the device 300 is transferred away from the device 300 along two main paths: (1) via conduction through solid high thermal conductivity material sections and (2) via mass transport via vapor sections. The distribution of the heat load via two paths serves to lessen the heat load into the VC, such that the VC does not go into dry out. The result is a construction that is more effective than a copper only construction because of the benefit of low thermal resistance in the vapor sections and more effective than a VC only construction because the VC does not carry the full device heat load, and therefore does not go into dry out. In general, the internal construction of the VC heat sink 100 utilizes a layered configuration.

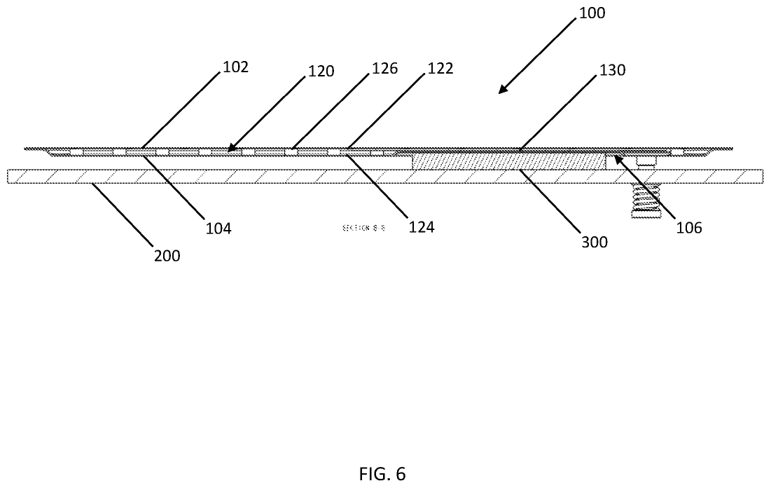

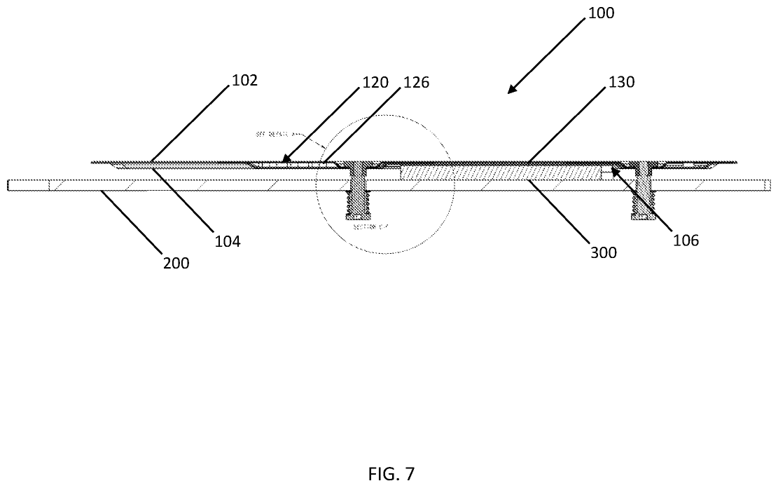

Referring to FIGS. 6-8, the VC heat sink 100 includes, removed from the PCB 200 and device 300 inwards, the high thermal conductivity outer planar member 102, an outer wick layer 122, a VC cavity 120, an inner wick layer 124, and the high thermal conductivity inner planar member 104. The outer planar member 102 and the inner planar member 104 may be manufactured from the same or different high thermal conductivity material, such as a metallic material (e.g., copper), graphite, or the like, and are joined together to form the sealed VC cavity 120 in which a fluid (liquid and vapor) and the other components are contained to perform heat transfer functions. The use of either of the outer wick layer 122 and the inner wick layer 124 is optional. These wick layers 122, 124 are manufactured from a porous wicking material that wicks the fluid, as a liquid, from cool regions to hot regions within the VC cavity 120, where the fluid evaporates and is then transported, as a vapor, from the hot regions to the cool regions within the VC cavity 120. In this manner, heat is transported from the hot regions to the cool regions of the VC heat sink 100, where the heat is transferred to a thermally coupled, external cooling air flow, solid heat sink, and/or liquid cooling device. The spacing between the outer planar member 102 and the inner planar member 104 and the integrity of the VC cavity 120 is maintained by a plurality of pillar structures 126 disposed between the outer planar member 102 and the inner planar member 104, optionally through or adjacent to the outer wick layer 122 and the inner wick layer 124. These pillar structures 126 may be manufactured from a rigid or semirigid material that is either porous (allowing the fluid to pass through) or solid (not allowing the fluid to pass through).

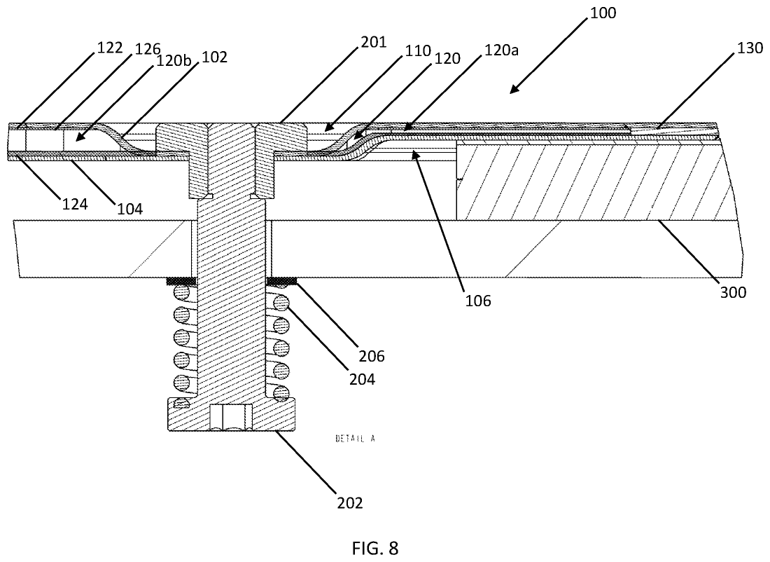

As best illustrated in FIG. 8, the VC cavity 120 may be a continuous cavity throughout the interior of the VC heat sink 100, or it may be made up of a plurality of separate, individual cavities, each extending from the region of the device 300 to a region adjacent to the device 300. This separation may be provided by the pillar structures 126 and/or other walls, dividers, etc. As illustrated, the VC cavity 120 typically has a thinner region 120a in the area of the device 300 and a thicker region 120b in areas adjacent to the device 300, due to constraints introduced by the presence of the device 300 and the conformal recess 106 of the inner planar member 104. For example, given a 0.9 mm VC heat sink envelope over a 55 W device 300, the high thermal conductivity skin layers 102, 104 may each be 0.2 mm thick, leaving 0.5 mm for wick layers 122, 124, the vapor cavity 120, and an intervening solid high thermal conductivity structure 130, with more space available adjacent to the device 300 than over the device 300.

The solid high thermal conductivity structure 130 is disposed within the VC cavity 120 over the device 300 and is thermally coupled to the outer planar member 102 and the inner planar member 104. The solid high thermal conductivity structure 130 may be manufactured from a metallic material (e.g., copper), graphite, or the like and preferably extends from the middle, hot region of the device 300 to cooler regions adjacent to the device 300. As described below, the solid high thermal conductivity structure may have a variety of shapes. As used here throughout, “solid” does not mandate an absolute lack of porosity, voids, or spaces, but, rather, refers to the solid high thermal conductivity structure 130 being sufficiently solid that it effectively and efficiently conducts heat. Thus, “solid” is a relative term as compared to the surrounding “fluid” within the VC cavity 120. “Solid” should be interpreted in all embodiments and examples to refer to a substantially sold structure, as compared to the surrounding fluid, whether or not porosity, voids, or spaces are also present.

The layers of the VC heat sink 100 are connected by soldering, brazing, heat fusing, or any technique normally used in the VC industry. The VC cavity 120 is filled with the working fluid, again, by any technique normally used in the VC industry. The volume between the outer planar member 102 and the inner planar member 104 of the present disclosure, however, is not uniformly filled with vapor, but with solid high thermal conductivity material sections and vapor sections. These sections are arranged such that there is solid high thermal conductivity material conduction of heat from primarily the middle of the device 300 to some region(s) beyond the device perimeter, while vapor transports the heat everywhere else. In the above example, the heat load taken by the solid high thermal conductivity material may be 35 W, while the heat load taken by all combined vapor sections may be 20 W—an amount that the vapor can transport without dry out.

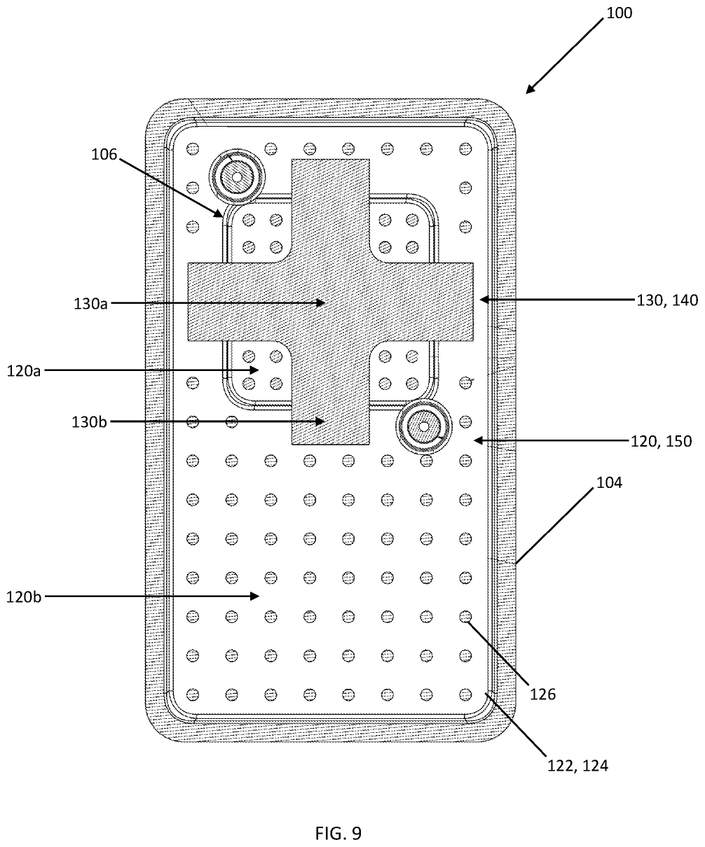

Referring to FIG. 9, in one example embodiment, it can be seen that the inner planar member 104 has a generally rectangular shape and defines the conformal recess 106 in the area of the device 300. Within the VC cavity 120 are the wick layer(s) 122, 124 and the pillar structures 126. In this embodiment, the solid high thermal conductivity structure 130 is a generally cross shaped structure that includes a center section 130a centered over the device 300 and perimeter sections 130b that extend to regions outside the perimeter of the device 300. Thus, the solid high thermal conductivity structure 130 serves to conduct heat from the center section 130a and the middle portion of the device 300 to the perimeter sections 130b and outside the perimeter of the device 300, where the heat may be exited from the VC heat sink 100. Between the perimeter sections, evaporation sections 120a and condensation sections 120b of the VC cavity 120 are formed, providing for thermal mass transport from the middle portion of the device 300 and the evaporation sections 120a to regions outside the perimeter of the device 300 corresponding to the condensation sections 120b, where the heat may again be exited from the VC heat sink 100. Because the solid high thermal conductivity structure 130 takes a portion of the heat load, as solid high thermal conductivity material section(s) or path(s) 140, the heat load of the VC cavity 120 does not cause dry out along the vapor section(s) or path(s) 150. Here, a contiguous VC cavity 120 is utilized.

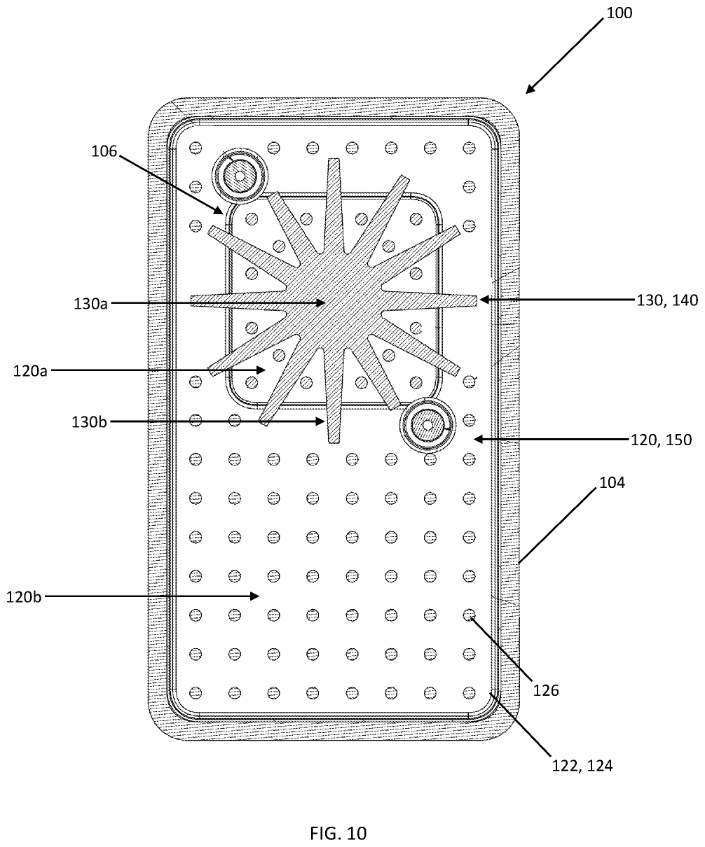

Referring to FIG. 10, in another example embodiment, it can be seen that the inner planar member 104 again has a generally rectangular shape and defines the conformal recess 106 in the area of the device 300. Within the VC cavity 120 are the wick layer(s) 122, 124 and the pillar structures 126. In this embodiment, the solid high thermal conductivity structure 130 is a generally star shaped structure that includes a center section 130a centered over the device 300 and perimeter sections 130b that extend to regions outside the perimeter of the device 300. Thus, the solid high thermal conductivity structure again serves to conduct heat from the center section 130a and the middle portion of the device 300 to the perimeter sections 130b and outside the perimeter of the device 300, where the heat may be exited from the VC heat sink 100. Between the perimeter sections, evaporation sections 120a and condensation sections 120b of the VC cavity 120 are formed, providing for thermal mass transport from the middle portion of the device 300 and the evaporation sections 120a to regions outside the perimeter of the device 300 corresponding to the condensation sections 120b, where the heat may again be exited from the VC heat sink 100. Because the solid high thermal conductivity structure 130 takes a portion of the heat load, as solid high thermal conductivity material section(s) or path(s) 140, the heat load of the VC cavity 120 does not cause dry out along the vapor section(s) or path(s) 150. Here, again, a contiguous VC cavity 120 is utilized.

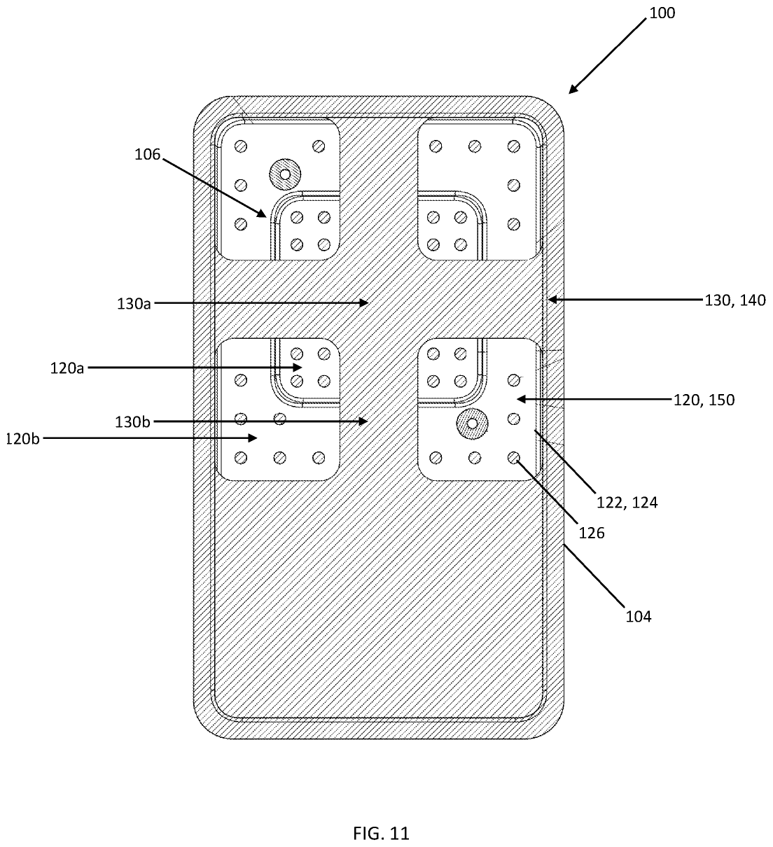

Referring to FIG. 11, in a further example embodiment, it can be seen that the inner planar member 104 again has a generally rectangular shape and defines the conformal recess 106 in the area of the device 300. Within the VC cavity 120 are the wick layer(s) 122, 124 and the pillar structures 126. In this embodiment, the solid high thermal conductivity structure 130 is a generally planar structure that includes a cross shaped center section 130a centered over the device 300 and a planar perimeter section 130b that extends to regions outside the perimeter of the device 300. Thus, the solid high thermal conductivity structure again serves to conduct heat from the center section 130a and the middle portion of the device 300 to the perimeter section 130b and outside the perimeter of the device 300, where the heat may be exited from the VC heat sink 100. The cross shaped center section defines separate evaporation sections 120a and condensation sections 120b of the VC cavity 120, providing for thermal mass transport from the middle portion of the device 300 and the evaporation sections 120a to regions outside the perimeter of the device 300 corresponding to the condensation sections 120b, where the heat may again be exited from the VC heat sink 100. Because the solid high thermal conductivity structure 130 takes a portion of the heat load, as solid high thermal conductivity material section(s) or path(s) 140, the heat load of the VC cavity 120 does not cause dry out along the vapor section(s) or path(s) 150. Here, separate VC cavities 120 are utilized.

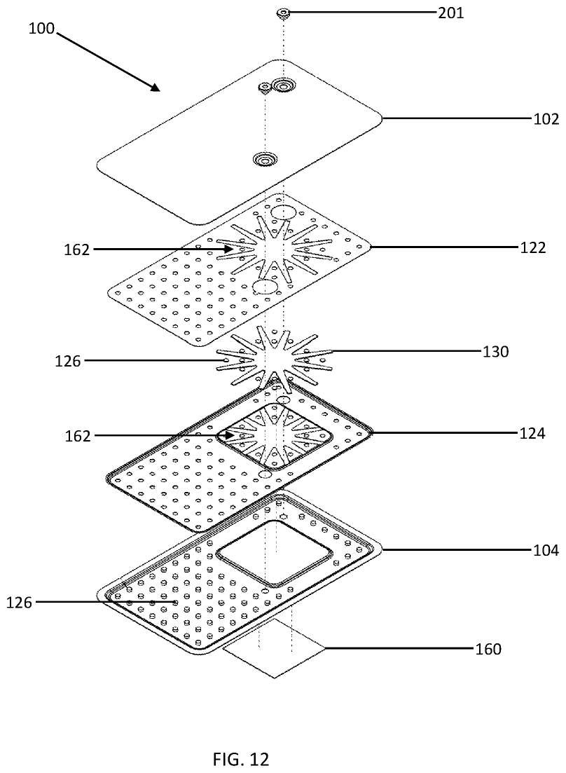

Referring to FIG. 12, in a somewhat clearer exploded view, the VC heat sink 100 again includes, removed from the PCB 200 and device 300 inwards, the high thermal conductivity outer planar member 102, the outer wick layer 122, the VC cavity 120, the inner wick layer 124, and the high thermal conductivity inner planar member 104. The outer planar member 102 and the inner planar member 104 may be manufactured from the same or different thermally conductive high thermal conductivity material, such as a metallic material (e.g., copper), graphite, or the like, and are joined together to form the sealed VC cavity 120 in which the fluid (liquid and vapor) and the other components are contained to perform heat transfer functions. The use of either of the outer wick layer 122 and the inner wick layer 124 is optional. These wick layers 122, 124 are manufactured from a porous wicking material that wicks the fluid, as a liquid, from cool regions to hot regions within the VC cavity 120, where the fluid evaporates and is then transported, as a vapor, from the hot regions to the cool regions within the VC cavity 120. In this manner, heat is transported from the hot regions to the cool regions of the VC heat sink 100, where the heat is transferred to a thermally coupled, external cooling air flow, solid heat sink, and/or liquid cooling device. The spacing between the outer planar member 102 and the inner planar member 104 and the integrity of the VC cavity 120 is maintained by the plurality of pillar structures 126 disposed between the outer planar member 102 and the inner planar member 104, optionally through or adjacent to the outer wick layer 122 and the inner wick layer 124. These pillar structures 126 may be manufactured from a rigid or semirigid material that is either porous (allowing the fluid to pass through) or solid (not allowing the fluid to pass through).

Again, the VC cavity 120 may be a continuous cavity throughout the interior of the VC heat sink 100, or it may be made up of a plurality of separate, individual cavities, each extending from the region of the device 300 to a region adjacent to the device 300. This separation may be provided by the pillar structures 126 and/or other walls, dividers, etc. The VC cavity 120 typically has a thinner region 120a in the area of the device 300 and a thicker region 120b in areas adjacent to the device 300, due to constraints introduced by the presence of the device 300 and the conformal recess 106 of the inner planar member 106.

The solid high thermal conductivity structure 130 is disposed within the VC cavity 120 over the device 300 and is thermally coupled to the outer planar member 102 and the inner planar member 104. The solid high thermal conductivity structure 130 may be manufactured from a metallic material (e.g., copper), graphite, or the like and preferably extends from the middle, hot region of the device 300 to cooler regions adjacent to the device 300.

The layers of the VC heat sink 100 are connected by soldering, brazing, heat fusing, or any technique normally used in the VC industry. The VC cavity 120 is filled with the working fluid, again, by any technique normally used in the VC industry. The VC cavity 120 of the present disclosure, however, is not uniformly filled with vapor, but with solid high thermal conductivity material sections and vapor sections. These sections are arranged such that there is solid high thermal conductivity material conduction of heat from primarily the middle of the device 300 to some region(s) beyond the device perimeter, while vapor transports the heat everywhere else.

Further, FIG. 12 shows the thermal interface material or layer 160 disposed between the inner planar member 104 and the device, potentially within the conformal recess 106. This thermal interface material or layer serves to thermally couple the VC heat sink 100 to the device 300 for maximum efficiency. Further, FIG. 12 shows that the wick layers 122, 124 may include cutouts 162 designed to accommodate the solid high thermal conductivity structure 130, such that the solid high thermal conductivity structure may make direct thermal contact with the planar members 102, 104.

Although the present disclosure is illustrated and described with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A hybrid conductor-vapor chamber heat sink, comprising:
an inner planar member adapted to be disposed adjacent to, in part, a printed circuit board and, in part, a device disposed on the printed circuit board;
an outer planar member coupled to the inner planar member to form a sealed vapor chamber cavity adapted to contain a fluid; and
a solid high thermal conductivity structure disposed between the inner planar member and the outer planar member within the vapor chamber cavity, wherein a center section of the solid high thermal conductivity structure is located coincident with a middle portion of the device and one or more perimeter sections of the solid high thermal conductivity structure are located coincident with one or more areas outside a perimeter of the device on the printed circuit board.

2. The hybrid conductor-vapor chamber heat sink of claim 1, wherein:
the solid high thermal conductivity structure provides a thermal conduction path to transfer heat from the center section of the solid high thermal conductivity structure to the one or more perimeter sections of the solid high thermal conductivity structure and correspondingly from the middle portion of the device to the one or more areas outside the perimeter of the device within the vapor chamber cavity; and
the vapor chamber cavity provides a thermal mass transfer path to transfer heat from an evaporation portion of the vapor chamber cavity, where the fluid undergoes phase change from liquid to vapor, to a condensation portion of the vapor chamber cavity, where the fluid undergoes phase change from vapor to liquid, and correspondingly from the middle portion of the device to the one or more areas outside the perimeter of the device within the vapor chamber cavity.

3. The hybrid conductor-vapor chamber heat sink of claim 2, wherein the thermal conduction path takes a portion of a heat load of the device and the thermal mass transfer path takes another portion of the heat load of the device, such that the vapor chamber cavity does not enter a dry out mode.

4. The hybrid conductor-vapor chamber heat sink of claim 1, further comprising one or more of an inner wick layer and an outer wick layer disposed within the vapor chamber cavity between the inner planar member and the outer planar member.

5. The hybrid conductor-vapor chamber heat sink of claim 1, wherein the inner planar member defines a conformal recess in which the device is disposed, wherein the vapor chamber cavity is relatively thinner in an area of the conformal recess and relatively thicker around the conformal recess, and wherein the solid high thermal conductivity structure is located, at least in part, coincident with the conformal recess within the vapor chamber cavity.

6. The hybrid conductor-vapor chamber heat sink of claim 1, further comprising a plurality of pillar structures disposed between the inner planar member and the outer planar member and adapted to maintain the integrity of the vapor chamber cavity.

7. The hybrid conductor-vapor chamber heat sink of claim 1, further comprising a thermal interface material disposed between the inner planar member and a surface of the device.

8. The hybrid conductor-vapor chamber heat sink of claim 1, wherein the solid high thermal conductivity structure divides the vapor chamber cavity into a plurality of separate vapor chamber cavities.

9. The hybrid conductor-vapor chamber heat sink of claim 1, wherein the inner planar member, the outer planar member, and the solid high thermal conductivity structure are each manufactured from one of copper and graphite.

10. A network element, comprising:
a printed circuit board;
a device disposed on the printed circuit board; and
a hybrid conductor-vapor chamber heat sink, comprising:
an inner planar member adapted to be disposed adjacent to, in part, the printed circuit board and, in part, the device;
an outer planar member coupled to the inner planar member to form a sealed vapor chamber cavity adapted to contain a fluid; and
a solid high thermal conductivity structure disposed between the inner planar member and the outer planar member within the vapor chamber cavity, wherein a center section of the solid high thermal conductivity structure is located coincident with a middle portion of the device and one or more perimeter sections of the solid high thermal conductivity structure are located coincident with one or more areas outside a perimeter of the device on the printed circuit board.

11. The network element of claim 10, wherein:
the solid high thermal conductivity structure provides a thermal conduction path to transfer heat from the center section of the solid high thermal conductivity structure to the one or more perimeter sections of the solid high thermal conductivity structure and correspondingly from the middle portion of the device to the one or more areas outside the perimeter of the device within the vapor chamber cavity; and
the vapor chamber cavity provides a thermal mass transfer path to transfer heat from an evaporation portion of the vapor chamber cavity, where the undergoes phase change from liquid to vapor, to a condensation portion of the vapor chamber cavity, where the fluid undergoes phase change from vapor to liquid, and correspondingly from the middle portion of the device to the one or more areas outside the perimeter of the device within the vapor chamber cavity.

12. The network element of claim 11, wherein the thermal conduction path takes a portion of a heat load of the device and the thermal mass transfer path takes another portion of the heat load of the device, such that the vapor chamber cavity does not enter a dry out mode.

13. The network element of claim 10, wherein the hybrid conductor-vapor chamber heat sink further comprises one or more of an inner wick layer and an outer wick layer disposed within the vapor chamber cavity between the inner planar member and the outer planar member.

14. The network element of claim 10, wherein the inner planar member defines a conformal recess in which the device is disposed, wherein the vapor chamber cavity is relatively thinner in an area of the conformal recess and relatively thicker around the conformal recess, and wherein the solid high thermal conductivity structure is located, at least in part, coincident with the conformal recess within the vapor chamber cavity.

15. The network element of claim 10, wherein the hybrid conductor-vapor chamber heat sink further comprises a plurality of pillar structures disposed between the inner planar member and the outer planar member and adapted to maintain the integrity of the vapor chamber cavity.

16. The network element of claim 10, wherein the hybrid conductor-vapor chamber heat sink further comprises a thermal interface material disposed between the inner planar member and a surface of the device.

17. The network element of claim 10, wherein the solid high thermal conductivity structure divides the vapor chamber cavity into a plurality of separate vapor chamber cavities.

18. The network element of claim 10, wherein the inner planar member, the outer planar member, and the solid high thermal conductivity structure are each manufactured from one of copper and graphite.

19. A method for cooling a device disposed on a printed circuit board, comprising:
providing a thermal conduction path to transfer heat from a middle portion of the device to the one or more areas outside the perimeter of the device within a vapor chamber cavity; and
providing a thermal mass transfer path to transfer heat from the middle portion of the device to the one or more areas outside the perimeter of the device within the vapor chamber cavity;
wherein the thermal conduction path takes a portion of a heat load of the device and the thermal mass transfer path takes another portion of the heat load of the device, such that the vapor chamber cavity does not enter a dry out mode.

20. The method of claim 19, wherein:
the thermal mass transfer path comprises the vapor chamber cavity containing a fluid provided between an inner planar member and an outer planar member of a hybrid conductor-vapor chamber heat sink, the vapor chamber cavity transferring heat from the evaporation portion of the vapor chamber cavity, where the fluid undergoes phase change from liquid to vapor, to a condensation portion of the vapor chamber cavity, where the fluid undergoes phase change from vapor to liquid; and
the thermal conduction path comprises a solid high thermal conductivity structure disposed between the inner planar member and the outer planar member within the vapor chamber cavity, wherein a center section of the solid high thermal conductivity structure is located coincident with a middle portion of the device and one or more perimeter sections of the solid high thermal conductivity structure are located coincident with one or more areas outside the perimeter of the device, the solid high thermal conductivity structure transferring heat from the center section of the solid high thermal conductivity structure to the one or more perimeter sections of the solid high thermal conductivity structure.
